(19) United States
(12) Patent Application Publication
(10) Pub. No.: US 2026/0031595 A1
(43) Pub. Date: Jan. 29, 2026

(54) An optical assembly and method for providing a multifrequency resonator-based frequency comb

(71) Applicants: ENLIGHTRA SÀRL, Renens VD (CH); DEUTSCHES ELEKTRONEN-SYNCHROTRON DESY, Hamburg (DE)

(72) Inventors: Tobias Herr, Hamburg (DE); Alexander Ulanov, Hamburg (DE); Thibault Wildi, Hamburg (DE); Maxim Karpov, Chavannes-près-Renens (CH)

(21) Appl. No.: 19/151,768

(22) PCT Filed: Jan. 3, 2024
(86) PCT No.: PCT/EP2024/050096

§ 371 Date: Jul. 29, 2025

(30) Foreign Application Priority Data
Jan. 30, 2023 (CH) CH000074/2023

(51) Int. Cl. H01S 5/065; G02F 1/35; G02F 1/365; H01S 5/026; H01S 5/062; H01S 5/12

(52) U.S. Cl. CPC H01S 5/0656; G02F 1/3513; G02F 1/365; H01S 5/0261; H01S 5/0622; H01S 5/12; G02F 2203/15; G02F 2203/56

(57) ABSTRACT

According to the present invention there is provided optical assembly (1) comprising. a laser (2) which is operable to emit light: an optical wave guide (3) having an input (3a) and an output (3b). the input (3a) of the optical wave guide (3) being optically coupled to the laser (2) so that the laser (2) can input light to the wave guide (3): a resonator (5) which is optically coupled to the wave guide (3) between the input (3a) of the wave guide (3) and the output (3b) of the wave guide (3): and wherein the resonator (5) has a resonant frequency. and wherein the resonator (5) defines an optical path (11): and wherein the resonator (5) is configured so that said optical path (11) is a closed loop: and wherein the resonator (5) is configured to have a periodic change in optical characteristics along said optical path (11) so that the resonator (5) can provide a backreflection which is at the resonant frequency of the resonator: and wherein the periodic change in optical characteristics along said optical path (11) provide an amount of said backreflection, which will provide a first detuning range in which self-injection locking of the laser using said backreflection is achieved, and. a second detuning range wherein a multifrequency comb can be generated within the resonator (5): and wherein the first and second ranges at least partially overlap, so that both self-injection locking of the laser will occur and an optical resonator-based multifrequency comb is output from the wave guide (3), when the assembly (1) is in operation. There is further provided a corresponding method of providing a optical resonator-based frequency comb at an output of a waveguide, using said assembly (1).

### FIELD OF THE INVENTION

The present invention concerns an optical assembly and method for providing a multifrequency optical resonator-based frequency comb; in particular the present invention concerns an optical assembly and method for providing a multifrequency optical microresonator-based frequency comb while also achieving self-injection-locking of a laser.

### BACKGROUND

A key challenge for optical microresonator-based or resonator-based frequency combs is maintaining a suitable frequency detuning between driving laser frequency and the resonator's resonance frequency. This detuning is unstable when thermo-optic effect causes the abrupt change in the resonator's resonance frequency or when laser frequency or microresonator's resonant frequency experiences thermal drift on a longer time scale. Self-injection locking (SIL) which enables locking the laser frequency to the resonator's resonance frequency and additionally provides significant narrowing of the laser line and reducing its phase noise can elegantly address this challenge, however, SIL typically relies on the optical feedback and resonant backreflection from the resonator caused by random imperfections in the resonator's optical characteristics. In other words, in existing assemblies the backreflected light has a random and often low amplitude of the backreflected light at particular resonance frequency that is dictated by the random amplitude and spatial frequency characteristics of the resonator's imperfections.

In existing assemblies, a strong backreflection is required to achieve satisfactory SIL which enables higher frequency detuning between laser frequency and resonator's resonance frequency. However, the strong backreflection with usual resonators is often connected with lower Q-factor and hence will result in an increased parametric threshold pump power. The parametric threshold pump power is an important parameter which defines laser light power density in the microresonator sufficient to initiate parametric process, namely four waves mixing leading to conversion of two photons of the pumping laser to two photons with the frequencies corresponding to resonant frequencies which are correspondingly lower and higher than the pumping laser frequency by one or multiple Free Spectral Range (FSR) values, where FSR is a spacing between resonance modes in a resonator. Below this threshold pump power there will be no multifrequency resonator-based frequency comb generated within the resonator. The generation of the multifrequency optical resonator-based frequency comb in resonator is necessary in order to provide a multifrequency optical resonator-based frequency combs at the output of the optical assembly.

According to the described trade-off between achieving satisfactory SIL and generating multifrequency optical resonator-based frequency comb existing optical assemblies are often unable to provide both the phenomena at the same time or these phenomena are provided with a nonoptimal manner leading to unstable or unreliable generation of the optical resonator-based frequency comb due to environmental fluctuations: if the existing optical assembly is optimized for satisfactory SIL then no multifrequency comb can generated within the resonator, so they will be unable to provide multi-frequency optical microresonator-based or resonator-based frequency combs at the output of the assembly; conversely, if the resonator in the existing assemblies is optimized for generation of multifrequency optical resonator-based frequency comb with pumping by some narrow linewidth laser but satisfactory SIL are not achieved with the assembly, then they will be unable to provide optical resonator-based frequency comb at the output of the assembly. Furthermore, if the resonator in the existing assemblies has a reduced number of imperfections (so that it is optimised for high-Q for example), then the backscattering will be too weak to enable the both the generation of a resonator-based comb and satisfactory SIL.

It is an aim of the present invention to obviate, or mitigate, at least some of the disadvantages associated with existing assemblies and methods.

### SUMMARY OF THE INVENTION

According to the present invention, this aim is achieved by an optical assembly comprising, a laser which is operable to emit light; an optical wave guide having an input and an output, the input of the optical wave guide being optically coupled to the laser so that the laser can input light to the wave guide; a resonator which is optically coupled to the wave guide between the input of the wave guide and the output of the wave guide; and wherein the resonator has a resonant frequency, and wherein the resonator defines an optical path; and wherein the resonator is configured so that said optical path is a closed loop; and wherein the resonator is configured to have a periodic change in optical characteristics along said optical path so that the resonator can provide a backreflection which is at the resonant frequency of the resonator; and wherein the periodic change in optical characteristics along said optical path provide an amount of said backreflection, which will provide a first detuning range in which self-injection locking of the laser using said backreflection is achieved, and, a second detuning range wherein a multifrequency comb can be generated within the resonator; and wherein the first and second ranges at least partially overlap, so that both self-injection locking of the laser will occur and an optical resonator-based multifrequency comb is output from the wave guide, when the assembly is in operation.

The resonator is preferably a microresonator and preferably the optical resonator-based multifrequency comb is a microresonator-based multifrequency comb.

The resonator may have a plurality of resonant frequencies, and the resonator is preferably configured to have a periodic change in optical characteristics along said optical path so that the resonator can provide a backreflection which is at a selected one of said resonant frequencies of the resonator. The selected one of said resonant frequencies of the resonator is preferably dependent on the periodicity of the periodic change in optical characteristics along said optical path.

The resonator may have a plurality of resonant frequencies, and the resonator is preferably configured to have a periodic change in optical characteristics along said optical path so that the resonator can provide a main backreflection which is at a selected one of said resonant frequencies of the resonator, and also to provide backreflection of additional multiple frequencies which can be used to tailor properties of the resonator (such as resonator dispersion for shaping the frequency comb spectra). In this case the amount of backreflection of the selected resonant frequency will be far greater than the amount of backreflection of the backreflection of the additional multiple frequencies.

A resonator-based multifrequency comb is a multifrequency comb which was generated in a resonator. A multi frequency comb can be generated in a resonator using any suitable mean; for example a multi frequency comb can be generated in a resonator by solitions, such as dissipative kerr solitions for example, which are generated in the resonator.

In another example a multi frequency comb can be generated in a resonator by platicons which are generated in the resonator, or other forms of four-wave mixing based on the third order Kerr-nonlinearity. In yet another example the frequency comb can be generated by second order nonlinear processes.

In a preferred embodiment the second detuning range is a range wherein frequency combs, can be generated within the resonator. In an embodiment the second detuning range is a range wherein dissipative kerr solitions can be generated within the resonator. In another embodiment the second detuning range is a range wherein platicons can be generated within the resonator.

The first detuning range is a range of detuning values which can be provided using said backreflection while maintaining the self-injection locking. The width of the first detuning range is between a minimum detuning value which can be provided using said backreflection while maintaining the self-injection locking and a maximum detuning value which can be provided using said backreflection while maintaining the self-injection locking.

Detuning is the difference between a frequency of light emitted by the laser into the waveguide, and the resonant frequency of the resonator. The resonator may have a plurality of resonant frequencies; and detuning may be the difference between a predefined frequency of light emitted by the laser into the waveguide, and a selected one of the resonant frequencies of the resonator. It should be understood that the detuning can be adjusted by changing the frequency of light emitted by the laser into the wave guide and/or by changing the resonant frequency of the resonator; in other words changing the frequency of light emitted by the laser into the waveguide and/or changing the resonant frequency of the resonator, will change the difference between the frequency of light emitted by the laser into the waveguide and the resonant frequency of the resonator. For example, the resonator's resonance frequency may be changed using a microheater which is attached to the resonator and which is operable to thermally change the refractive index of the resonator; or, in an embodiment in which the resonator comprises piezo electric material, using a piezo actuator to change the refractive index of the resonator by operating the piezo actuator to apply pressure to the resonator.

In an embodiment the phase of light emitted from the laser into the waveguide and received by the resonator, and the phase of the backreflection, are tuned to maximize the first detuning range. For example, the tuning of the phase may be achieved using microheaters, and/or piezo actuators, and/or through electro-optic materials which are subject to a tuneable electric field.

Preferably, the first detuning range is a range of detuning any value of which can be provided by applying frequency offset to the laser and/or applying frequency offset to the resonant frequency of the resonator while maintaining the self-injection locking of the laser in the assembly, using the backreflection, when the assembly is in operation. The phase of light emitted by the laser into the waveguide and received by the resonator, and, the phase of the backreflection, can be tuned to maximize the first detuning range.

Preferably, the second detuning range, is a range of detuning values (each of which may be achieved by applying frequency offset to the laser and/or applying frequency offset to the resonant frequency of the resonator) over which at least two frequencies are generated in the resonator so that a optical resonator-based multifrequency comb is provided at the output of the waveguide.

It should be understood that the resonator may be configured in many different ways so as to have a periodic change in optical characteristics along said optical path which will achieve an overlap of the first and second ranges. Various different designs of the resonator can be tested under a simulation to determine if they will achieve an overlap of the first and second ranges. Various exemplary designs for the resonator which achieves an overlap of the first and second ranges are specifically described in the present application; however, it will be understood that other designs are also possible.

In an embodiment of the assembly the amount of said backreflection γ is large enough so that single DKS pulses are generated. Preferably, γ>ƒ=²κ/8, wherein ƒ=\sqrt{8ηω₀cn₂P/(κ²n²V_{eff})} is the normalized pump power or power of the laser 2 in the assembly 1 expressed in the dimensionless units, with the coupling coefficient η=½ (critical coupling meaning that no light is passing through the waveguide after the light beam is coupled into the optical ring resonator except the light that coupled out from the resonator through the same coupling element)., ω₀ is the resonance frequency of the resonator's mode which coincides with the light frequency of laser 2 in the assembly 1, c the speed of light in vacuum, P the input pump power in the power units, n the refractive index, n₂ nonlinear index meaning the dependency of refractive index from the laser intensity when intense laser beam passes through material (n=n₀+n₂·I, where I is intensity of laser light) and V_{eff} the mode volume meaning the volume occupied by light field in the resonator that is not equal to the volume of resonator's waveguide; γ is half of the mode splitting and κ is the resonance width.

In an embodiment of the assembly the amount of said backreflection γ is small enough so that the parametric threshold can be reached. Preferably, for an available amount of laser power (pump power) ƒ, γ should be chosen so that the following inequality holds:

$${f}^{2} > \frac{4 γ}{κ} + κ / γ$$

wherein all quantities are defined as before.

In an embodiment of the assembly the first and second ranges overlap by at least an amount equal to a line width of the laser. Preferably the first and second ranges overlap by an amount which is equal to one or multiple resonator resonance linewidths.

In an embodiment of the assembly the resonator has a plurality of resonant frequencies; and wherein the resonator is configured to have a periodic change in optical characteristics along said optical path so that the resonator can provide a backreflection which is at a selected one of said plurality of resonant frequencies of the resonator.

In an embodiment of the assembly the resonator-based multi-frequency comb which is output from the wave guide comprises at least two frequencies that were generated in the resonator.

In an embodiment of the assembly a difference between a frequency of light emitted by the laser into the wave guide, and the resonance frequency of the laser, is equal to a value which is within said overlap of the first and second ranges.

In an embodiment of the assembly the periodicity ‘P’ of the periodic change in optical characteristics along said optical path is equal to P=L(2m), wherein ‘L’ is the length of the optical path and ‘m’ is an integer.

In an embodiment of the assembly the number of periodic changes in optical characteristics along said optical path, is an even number. In other words, if ‘L’ is the length of the optical path and ‘w’ is the resonant wavelength of the resonant light of which a (partial) backreflection is generated in the resonator by the periodic changes in optical characteristics, then w=L/m, wherein ‘m’ is an integer. The periodicity is then P is then P=L/(2m).

It should be understood that if the wavelength ‘w’ of the resonant light in the resonator changes due to a change of resonator properties that are not the previously described periodic changes that generate the backreflection, then also the periodicity of the periodic changes can change to locally maintain the relation that the periodicity P is equal to w/2. An example would be a race-track resonator where the curvature of the resonator waveguide is not constant along the path that defines the resonator. Another example would be a resonator whose mean-waveguide width is not constant along the path, where mean waveguide width is defined as the mean width along the optical path over a distance that corresponds to P.

In an embodiment of the assembly the periodicity of the periodic changes in optical characteristics along said optical path may be slightly varied to mitigate an uncertainty in the ideal periodicity. This can in particular be useful in a resonator whose properties (other than the property of creating the backreflection) vary along the optical path, e.g. race-track resonators, wherein the curvature is not constant. Preferably the variation the periodicity of the periodic changes in optical characteristics along said optical path is smaller than 10%.

In an embodiment of the assembly the laser is operable to emit light into the waveguide which comprises a predefined frequency wherein the difference between said predefined frequency of the light emitted by the laser into the waveguide and said selected one of said plurality of resonant frequencies of the resonator, is within a predefined range. In an embodiment of the assembly the predefined range is from κ to 10κ, wherein κ is a resonance width of the resonator.

In an embodiment of the assembly the resonator has a third order non-linearity.

In an embodiment of the assembly the resonator has a free-spectral range (FSR) in the range from 1 GHz to 1 THz.

In an embodiment of the assembly the resonator has a second order non-linearity.

In an embodiment of the assembly the laser comprises a semiconductor laser, and the semiconductor laser is detuned by applying a predefined injection current to an input of the semiconductor laser.

In an embodiment of the assembly the laser comprises a rare-Earth-based laser, and the laser is detuned by applying a predefined heating current, piezo actuation or electro-optic tuning.

In an embodiment of the assembly, the assembly further comprises a microheater, wherein the microheater is operably connected to the resonator so that the microheater is operable to heat the resonator to thermally change a refractive index of the resonator. The advantage of this feature is that the resonance frequency of the resonator can be detuned by the microheater; the microheater is controlled by an input voltage to the microheater; accordingly, the resonance frequency of the resonator can be detuned a predefined amount by applying a predefined level of voltage to the microheater.

In an embodiment of the assembly, the resonator comprises piezo electric material and the assembly further comprises a piezo stack actuator which is operably connected to the resonator, wherein the piezo stack actuator is operable to apply a stain to the resonator to change a refractive index of the resonator. The advantage of this feature is that the resonance frequency of the resonator can be detuned by the piezo stack actuator; the piezo stack actuator is controlled by an input voltage to the piezo stack actuator—the more voltage applied to the piezo stack actuator the more stress and tension that is created within the resonator—the stress and tension detunes the resonance frequency of the resonator; accordingly the resonance frequency of the resonator can be detuned a predefined amount by applying a predefined level of voltage to the piezo stack actuator.

In an embodiment of the assembly the resonator comprises an electro-optic material. The electro-optic material will enable tuning the resonance frequency of the resonator by applying an electric field to the resonator. Preferably the electric field is created using electrodes integrated in proximity of the resonator and an electric voltage can be applied to those electrodes.

In an embodiment of the assembly, the resonator is configured to have a periodic change in an effective index of refraction, along said optical path. The effective index or refraction is the effective refractive index perceived by the light inside the resonator. Specifically, the effective index of refraction defines the amount of change of the phase of the optical light over a certain distance of propagation.

In an embodiment of the assembly, the resonator is configured to have a periodic change in an index of refraction, along said optical path.

In an embodiment of the assembly the resonator is configured to have a periodic change in a material density heterogeneity, along said optical path.

In an embodiment of the assembly the resonator is configured to have a periodic change in geometry, along said optical path. In an embodiment of the assembly periodic changes in geometry occur an even number of times.

In an embodiment of the assembly periodic changes in optical characteristics along said optical path occur an even number of times.

In an embodiment of the assembly, the resonator comprises a plurality of corrugations, each of which have equal dimensions, which provide said periodic change in optical characteristics along said optical path. The number of corrugations may be in the range 20-200000.

The amplitude of each corrugation may be the same. The amplitude of each corrugation may be between 1 nm and 10 micrometers.

In an embodiment of the assembly the resonator is a ring shaped and the corrugations are arranged to point towards a centre of the ring shape; or wherein the corrugations are arranged to point away from a centre of the ring shaped.

In an embodiment of the assembly the corrugations are arranged to point towards the area enclosed by the resonator; or wherein the corrugations are arranged to point towards the area surrounding the resonator.

In an embodiment of the assembly each of said corrugations have a triangular prism form, and an angle between two adjacent corrugations is between 0-180 degrees.

In an embodiment of the assembly, the resonator comprises a plurality of holes defined therein (e.g. the resonator comprises a plurality of holes in the waveguides). Preferably said holes have a vertical orientation. Preferably each of said holes have equal dimensions. Said holes provide said periodic changes in optical characteristics along said optical path. The number of holes may be in the range 20-200000.

In an embodiment of the assembly, the periodic changes in optical characteristics of the resonator are only along a portion of said optical path. The resonator may comprise gradual (adiabatic) transition from a segment with period changes in optical characteristics to a segment which is without period changes in optical characteristics; this gradual transition may be used to reduce unwanted effects such loss or reflection at wavelength different from the desired wavelength.

In an embodiment of the assembly, the periodic changes in optical characteristics of the resonator are only the whole length of said optical path.

In an embodiment of the assembly the resonator comprises a photonic chip which comprises a cladding, and wherein said periodical changes in the optical characteristics of resonator are provided in the cladding. Most preferably the period changes in optical characteristics are located close to the resonator's waveguide. Preferably, the parts of the resonator have the periodical change of optical characteristics are connected with resonator's waveguide by an evanescent field. An assembly according to any one of the preceding claims, wherein the multi-frequency optical resonator-based frequency comb comprises at least two frequencies which were generated within the resonator.

In an embodiment of the assembly the resonator comprises a photonic crystal ring resonator.

In an embodiment of the assembly the resonator is optically coupled to the wave guide by means of an evanescent field.

In an embodiment of the assembly the input of the optical wave guide is optically coupled to the laser, so that the laser light frequency components which coincide in frequency with the resonator resonance frequencies can propagate along the waveguide to the resonator. In an embodiment of the assembly the laser comprises a Fabry-Pérot laser diode. When one of the frequencies of the Fabry Perot laser coincides with the resonance frequency of a micro resonator SIL occurs and the laser generates only one frequency.

According to a further aspect of the present invention there is provided a method of providing a multi-frequency optical resonator-based frequency comb, comprising the steps of, providing an assembly according to any one of the preceding claims; generating in the resonator a backreflection which has a predefined frequency, and using that backreflection for self-injection locking of the laser; and generating a plurality of frequencies in the resonator, so that a multi-frequency optical resonator-based frequency comb which comprises the plurality of frequencies that were generated in the resonator, is output from the assembly.

The resonator is preferably a microresonator and preferably the optical resonator-based multifrequency comb is a microresonator-based multifrequency comb.

The resonator may have a plurality of resonant frequencies, and the method may comprise the step of selecting one of said resonant frequencies; and wherein the resonator is preferably configured to have a periodic change in optical characteristics along said optical path so that the resonator can provide a backreflection which is at a selected one of said resonant frequencies of the resonator.

In an embodiment of the method the step of generating a plurality of frequencies in the resonator comprises generating optical resonator-based frequency comb in the resonator. A resonator-based multifrequency comb is a multifrequency comb which was generated in a resonator. A multi frequency comb can be generated in a resonator using any suitable mean; for example, a multi frequency comb can be generated in a resonator by solitions, such as dissipative kerr solitions for example, which are generated in the resonator. In another example a multi frequency comb can be generated in a resonator by platicons which are generated in the resonator.

In an embodiment of the method the step of generating a plurality of frequencies in the resonator comprises generating any one or more of, solitons and/or dissipative kerr solitions and/or platicons within the resonator.

In a preferred embodiment of the method the amount of backreflection which is generated, will provide a first detuning range in which self-injection locking of the laser using said backreflection is achieved, and, a second detuning range wherein an optical resonator-based frequency comb can be generated within the resonator, and wherein the first and second detuning ranges at least partially overlap, so that a multi-frequency microcomb is output from the waveguide, when the assembly is in operation.

The first detuning range is a range of detuning values which can be provided using said backreflection while maintaining the self-injection locking. The width of the first detuning range is between a minimum detuning value which can be provided using said backreflection while maintaining the self-injection locking and a maximum detuning value which can be provided using said backreflection while maintaining the self-injection locking.

In a preferred embodiment the second detuning range is a range wherein frequency combs, can be generated within the resonator. In an embodiment the second detuning range is a range wherein dissipative kerr solitions can be generated within the resonator. In another embodiment the second detuning range is a range wherein platicons can be generated within the resonator.

Preferably the method comprises the step of configuring the assembly so that there is self-injection locking of the laser; and then detuning the assembly so that a multi-frequency microcomb is output from the waveguide, while maintaining self-injection locking of the laser. Preferably the first detuning range any detuning value of which can be provided while maintaining the self-injection locking.

In an embodiment of the method the amount of backreflection which is generated, will provide a first detuning range in which self-injection locking of the laser using said backreflection is achieved, and, a second detuning range wherein kerr solitions and/or platicons can be generated within the resonator, and wherein the first and second ranges at least partially overlap, so that a multi-frequency microcomb is output from the wave guide, when the assembly is in operation.

In an embodiment of the method the method further comprises the steps of, providing detuning which is within said overlap of the first and second ranges, by applying a frequency offset to the laser and/or by applying a frequency offset to the resonant frequency of the resonator, so that both self-injection locking of the laser occurs and a multi-frequency optical resonator-based frequency comb is output from the wave guide.

In an embodiment of the method the method comprises, obtaining a graph depicting the relationship, between detuning provided by applying a frequency offset to the laser and/or detuning provided by applying a frequency offset to the resonant frequency of the resonator, an amount of backreflection generated in the resonator, an multifrequency optical resonator-based frequency comb range, and a self-injection locking range, of the assembly; identifying a region on the graph where the multifrequency optical resonator-based frequency comb existence range and self-injection locking range overlap; identifying a range, or level, for detuning offset to be provided by identifying on the graph a range, or level, of detuning offset which corresponds with said identified region.

The optical resonator-based frequency comb range is a range of detuning offsets and amount of backreflection, over which the assembly can operated to provide an optical resonator-based frequency comb at an output of the waveguide. The self-injection locking range comb range is a range of detuning offsets and amount of backreflection, over which self-injection locking of the laser will occur when the assembly is in operation.

The multifrequency optical resonator-based frequency comb existence range may comprises any one of a dissipative kerr solitions range, a solitions range, and/or a platicons range. The solitions range is a range of detuning offsets and amount of backreflection over which solitions will be generated in the resonator when the assembly is in operation. The dissipative kerr solitions range is a range of detuning offsets and amount of backreflection over which dissipative kerr solitions will be generated in the resonator when the assembly is in operation. The platicons range is a range of detuning offsets and amount of backreflection over which platicons will be generated in the resonator when the assembly is in operation.

In an embodiment of the method the method comprises the steps of, obtaining a graph depicting the relationship, between detuning provided by applying a frequency offset to the laser and/or detuning provided by applying a frequency offset to the resonant frequency of the resonator, an amount of backreflection generated in the resonator, a dissipative kerr solitions range, and a self-injection locking range, of the assembly; identifying a region on the graph where the dissipative kerr solitions range and self-injection locking range overlap; identifying a range, or level, for detuning offset to be provided by identifying on the graph a range, or level, of detuning offset which corresponds with said identified region.

In an embodiment of the method the method further comprises the step of adjusting the position of the laser so as to tune the phases of light which are emitted from the laser into the waveguide and received by the resonator, and to tune the backreflection, so as to maximize the size of the first detuning range.

In an embodiment of the method comprises, using a resistance microheater on the waveguide, and placed between laser and resonator, to thermally change the refractive index of the waveguide. A voltage is applied to the resistance microheater to cause the resistance microheater to thermally change the refractive index of the waveguide; the more voltage that is applied to the resistance microheater the more the microheater the bigger change in the refractive index of the waveguide.

In an embodiment of the method the method further comprises the step of, applying a detuning offset to the laser to maximize the size of the first detuning range, while also maintaining at least a partial overlap between the first and second detuning ranges. Adjusting the assembly (e.g. by applying an appropriate offset to the laser or to the resonant frequency of the resonator) to increase the amount of back reflection, will increase the size of the first detuning range. In an embodiment of the method the method comprises, applying a detuning offset to the laser so that frequency of light which is emitted by the laser into the waveguide and received by the resonator, and the frequency of the backreflection, are tuned to maximize the size of the first detuning range.

In an embodiment of the method the resonator has a plurality of resonant frequencies; and the method may comprise the step of selecting one of said resonant frequencies; and adjusting the resonator can provide a backreflection which is at a selected one of said plurality of resonant frequencies of the resonator.

### BRIEF DESCRIPTION OF THE DRAWINGS

Exemplary embodiments of the invention are disclosed in the description and illustrated by the drawings in which:

FIG. 1a illustrates an embodiment of an assembly of the present invention;

FIG. 1b is a graph showing the result of increased backreflection from the microresonator of the assembly in FIG. 1a having periodically changed optical characteristics along said optical path; Indicative transmission and reflection spectrum for the resonance with mode number m₀ exhibiting backreflection and two adjacent resonances m_{0±1}, separated by ±FSR.

FIG. 1c is a graph depicting the relationship, between the detuning offset applied to the laser, the level of backreflection, the Dissipative Kerr Solution existence range, and the Self-injection locking existence range, for the assembly of FIG. 1a, which is used in an embodiment of a method of the present invention.

FIG. 2a is a plot showing the backreflection level and spectra for resonator's resonance modes when resonance frequency of one of them (red dot) is matched with the spatial frequency of the periodically changed microresonator's optical characteristics along said optical path at the assembly in FIG. 1a;

FIG. 2b is a plot showing the comparison of the dependencies of the backreflection level for a microresonator's mode with engineered backreflection and microresonator's Q-factor from the amplitude of the periodically changed optical characteristics of the microresonator at the assembly in FIG. 1a;

FIG. 2c is a graph showing the comparison of the phase noise of the semiconductor distributed feedback (DFB) laser in free-running and SIL regimes realized without of optical microresonator-based frequency comb generation at the output of the assembly in FIG. 1a. The phase noise is measured through heterodyne detection with a reference narrow-linewidth laser;

FIG. 2d is a graph showing heterodyne beatnote signal between the narrow-linewidth reference laser oscillator and DFB laser in the free-running and SIL regime realized without of optical microresonator-based frequency comb generation at the output of the assembly in FIG. 1a;

FIG. 2e is a graph showing the optical spectrum of the DFB laser in SIL regime realized without of optical microresonator-based frequency comb generation at the output of the assembly in FIG. 1a;

FIG. 2f is a block diagram of a setup (CC, current controller; LD, laser diode; OSA and ESA, optical and electrical spectrum analyzers respectively; OSC, oscilloscope; CW, continuous-wave laser; PD, photodiode), used to demonstrate operation of the assembly in FIG. 1a;

FIG. 3a-1 depicts the optical spectrum measured at output from the assembly in FIG. 1a when the laser is in SIL regime and laser frequency detuning is not enough for multifrequency optical microresonator-based frequency comb generation;

FIG. 3a-2 depicts the optical spectrum measured at output from the assembly in FIG. 1a when the laser is in SIL regime and laser frequency detuning is enough for multifrequency optical microresonator-based frequency comb or Dissipative Kerr Soliton (DKS) generation;

FIG. 3a-3 depicts the optical spectrum measured at output from the assembly in FIG. 1a when the laser is in SIL regime and laser frequency detuning is large enough to get specific optical microresonator-based frequency comb or DKS generation with modulated mode spacing, so called breather DKS;

FIG. 3b is a block diagram of a setup (EOM-electrooptical modulator, FBG-fiber Bragg grating, PD-photodetector, ESA-electrical spectrum analyzer), used to measure mode spacing or repetition rate of the generated optical microresonator-based frequency comb at the output of the assembly in FIG. 1a;

FIG. 3c is a graph showing the measured SIL-optical microresonator-based frequency comb repetition rate or mode spacing signal at the output of the assembly in FIG. 1a using the setup in FIG. 3b. (2)—single DKS and (3)—breather DKS;

FIG. 3d is a graph showing total transmission (blue) and bandpass-filtered power (red; filter offset from the pump, indicates comb formation) measured during laser frequency scan at the output of the assembly in FIG. 1a. The orange line corresponds to the driving current;

FIG. 3e is a graph showing total transmission (blue) and bandpass-filtered power (red; filter offset from the pump, indicates comb formation) measured during laser frequency scan at the output of the assembly in FIG. 1a when in the assembly the conventional resonator without of periodically changed optical characteristics along said optical path is used. The orange line corresponds to the driving current;

FIGS. 4a-4k show various different exemplary implementations for the resonator having periodically changed optical characteristics along the optical path which can be used in the assembly in FIG. 1a.

### DETAILED DESCRIPTION OF EMBODIMENTS OF THE INVENTION

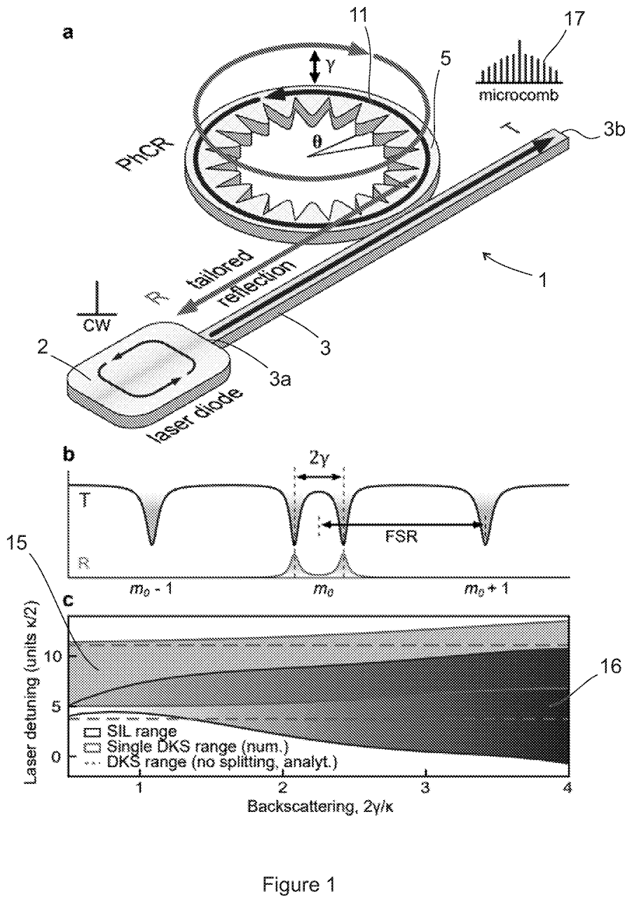

FIG. 1a is a perspective view of an optical assembly 1 according to an embodiment of the present invention. The assembly 1 comprises, a laser 2 which is operable to emit light. Most preferably the laser 2 is operable to emit light which has at least on spectral component with a predefined frequency. In operation of the assembly, frequency of the spectral component coincides with one of the resonance frequencies of resonator 5 or may be detuned from the resonance for some frequency value. In this example the laser 2 comprises a laser diode 2.

The assembly further comprise an optical wave guide 3 having an input 3a and an output 3b. The input 3a of the optical wave guide 3 is optically coupled to the laser 2 so that the laser 2 can input light to the wave guide 3. The output 3b of the optical wave guide 3 may define the output of the assembly 1. It should be understood that in the present application optically coupling of features can be done using any suitable means; so long as the features can transmit optical signals between one another then the features are optically coupled. Optically coupled includes, but is not limited to, the features being optically connected (e.g. an optical element connects between the two features so that the features can transmit optical signals between one another via the optical element).

The assembly 1 further comprises a resonator 5 which is optically coupled to the wave guide 3 between the input 3a of the wave guide 3 and the output 3b of the wave guide 3. In a preferred embodiment the resonator 5 is optically coupled to the wave guide 3 by means of an evanescent field

The resonator 5 defines an optical path 11 and is configured to have a periodic change in optical characteristics moving along said optical path 11. The resonator 5 has a resonant frequency (in an embodiment the resonator 5 has a plurality of resonant frequencies). The resonator 5 is configured so that said optical path 11 is a closed loop, so that the resonator 5 can provide a backreflection which is at one of the resonant frequencies of the resonator 5. In the assembly 1 the resonator 5 is a micro-resonator 5; however it should be understood that the invention is not limited to requiring a micro-resonator 5, rather any suitable resonator can be used in the assembly 1.

The periodic change in optical characteristics along said optical path 11 provide an amount of said backreflection, which will provide a first detuning range in which self-injection locking of the laser using said backreflection is achieved, and, a second detuning range wherein a multifrequency comb can be generated within the resonator 5. The first and second ranges at least partially overlap. Advantageously both self-injection locking of the laser will occur and an optical resonator-based multifrequency comb 17 is output from the wave guide 3, when the assembly 1 is in operation.

The periodic changes in optical characteristics moving along said optical path 11 enable a detuning of the assembly 1 (which may also be referred to as detuning offsets) to be achievable which will ensure both self-injection locking of the laser will occur and an optical resonator-based multifrequency comb 17 is output from the wave guide 3, when the assembly 1 is in operation.

The second detuning range is a range wherein frequency combs, can be generated within the resonator 5. In an embodiment the second detuning range is a range wherein dissipative kerr solitions can be generated within the resonator. In another embodiment the second detuning range is a range wherein platicons can be generated within the resonator.

The first detuning range is a range of detuning values which can be provided using said backreflection while maintaining the self-injection locking. The width of the first detuning range is between a minimum detuning value which can be provided using said backreflection while maintaining the self-injection locking and a maximum detuning value which can be provided using said backreflection while maintaining the self-injection locking.

Detuning (or detuning offset) is the difference between a frequency of light emitted by the laser into the waveguide, and the resonant frequency of the resonator. The resonator may have a plurality of resonant frequencies; and detuning may be the difference between a predefined frequency of light emitted by the laser into the waveguide, and a selected one of the resonant frequencies of the resonator. It should be understood that the detuning can be adjusted by changing the frequency of light emitted by the laser into the wave guide and/or by changing the resonant frequency of the resonator; in other words changing the frequency of light emitted by the laser into the waveguide and/or changing the resonant frequency of the resonator, will change the difference between the frequency of light emitted by the laser into the waveguide and the resonant frequency of the resonator. Thus the detuning of the assembly 1 (which may also be referred to as detuning offset) which is necessary to ensure both self-injection locking of the laser will occur and an optical resonator-based multifrequency comb is output from the wave guide 3, when the assembly 1 is in operation, may be achieved by applying a laser frequency detuning offset to the laser 2, or applying an offset to the resonant frequency of the resonator 5.

The multi-frequency optical resonator-based frequency comb 17 which is output from the wave guide 3 will comprise a plurality of frequencies (i.e. at least two frequencies) which coincide with resonator's resonance frequencies spaced by resonator's free spectral range (FSR) value and which were generated within the resonator 5. In the embodiment wherein the resonator is a microresonator, then a multi-frequency optical microresonator-based frequency comb 17 is output from the wave guide 3, when the assembly 1 is in operation.

Preferably in the assembly 1, the periodicity ‘P’ of the periodic change in optical characteristics along said optical path is equal to P=L/(2m), wherein ‘w’ is the wavelength of the resonant light of which a (partial) backreflection is generated in the resonator by the periodic structure, ‘L’ is the length of the optical path and ‘m’ is an integer. For example, the periodicity of the periodic changes in optical characteristics may be from 1 to 10⁵ the resonant frequency of the resonator 5.

Referring to FIG. 1c which shows a graph of the operational ranges of the assembly 1 shown in FIG. 1a. The graph depicts the relationship, between a detuning (shown on the y-axis) of the assembly 1 (which may be provided by applying a frequency offset to the laser and/or providing an offset to the resonant frequency of the resonator. In the case of exemplary graph shown in FIG. 1c the detuning of the assembly is achieved by applying an frequency offset to the laser 2, hence the title “Laser detuning (units k/2)” of the y-axis), an amount of backreflection generated in the resonator (shown on the x-axis entitled “backscattering, 2γ/k”), an multifrequency optical resonator-based frequency comb range 15 (shown as the red coloured region of the graph), and a self-injection locking range 16 (shown as the blue coloured region of the graph), of the assembly. The optical resonator-based frequency comb range 15 is a range of detuning (y-axis) of the assembly 1 (which may also be referred to as detuning offsets) over which the assembly can operated to provide an optical resonator-based frequency comb at an output of the waveguide, for a given amount of backscattering (i.e. for a specific value on the x-axis). The self-injection locking range 16 is a range of detuning (y-axis) of the assembly 1 (which may also be referred to as detuning offsets), over which self-injection locking of the laser will occur, for a given amount of backscattering (i.e. for a specific value on the x-axis), when the assembly is in operation.

In this particular embodiment, FIG. 1c depicts the relationship, between a detuning of the assembly (which could be achieved by applying an offset to the laser 2), the amount of backreflection at particular frequency provided by the resonator 5, the dissipative kerr solition range 15, and the self-injection locking range 16, for the assembly 1. The dissipative kerr solitions range is a range of detuning (y-axis) of the assembly over which dissipative kerr solitions will be generated in the resonator 5, for a given amount of backscattering (i.e. for a specific value on the x-axis), when the assembly is in operation. The self-injection locking range 16 is a range of detuning of the assembly 1 (which may also be referred to as detuning offsets) over which self-injection locking of the laser will occur, for a given amount of backscattering (i.e. for a specific value on the x-axis), when the assembly is in operation.

It should be understood that while the present application describes an example wherein the dissipative kerr solitions are generated in the resonator to generate a multifrequency microcomb at the output 3b, the present invention is not limited to requiring the generation of dissipative kerr solitions in the resonator; any means which can generate a multifrequency comb within the resonator can be used. For example, the multifrequency optical resonator-based frequency comb range could be any one of: a solitions range which is a range of detuning of the assembly 1 (which may also be referred to as detuning offsets) over which solitions will be generated in the resonator; or dissipative kerr solitions range which is a range of detuning of the assembly 1 (which may also be referred to as detuning offsets) over which dissipative kerr solitions will be generated in the resonator 5 when the assembly is in operation; or a platicons range which is a range of detuning of the assembly 1 (which may also be referred to as detuning offsets) over which platicons will be generated in the resonator when the assembly is in operation.

As can be seen from FIG. 1c, the assembly 1 has a first detuning offset range on the y-axis (which is from ‘5’ to ‘7’ at units of k/2 at amount of backreflection ‘1’ at units of 2γ/k and from ‘0’ to ‘10’ at units of k/2 at amount of backscattering 4 at units of 2γ/k, where k is the width of resonator's resonance and 2γ is the resonance frequency splitting which is proportional to the amount of backscattering), wherein the first detuning offset range is a range of detuning offset values which, when any one of the detuning offsets in the first range is applied to the laser 2, self-injection locking of the laser 2 in the assembly 1, using the backreflection provided by the resonator 5, will occur when the assembly 1 is in operation; and the assembly 1 has a second detuning offset range on the Y-axis (which is from ‘5’ to ‘11’ at units of k/2 at amount of backscattering ‘0’ and from ‘7’ to ‘14’ at units of k/2 at amount of backscattering 4 at units of 2γ/k, where k is the width of resonator's resonance and 2γ is the resonance frequency splitting which is proportional to the amount of backscattering wherein the second detuning offset range is a range of detuning offset values which, when any one of the detuning offsets in the second range is applied to the some narrow linewidth laser pumping the microresonator, dissipative kerr solitons are generated in the resonator 5 resulting in the generation of at least two frequencies in the resonator 5. Accordingly, the first range and second range partially overlap; specifically, the overlapping part of the first and second ranges is from ‘5’-‘7’ k/2 at amount of backscattering 2γ/k and from ‘6’-‘10’ k/2 at amount of backscattering 4·2γ/k, where k is the width of resonator's resonance and 2γ is the resonance frequency splitting which is proportional to the amount of backscattering. The laser 2 of the assembly 1, has a detuning offset which has a value which is within said overlapping part of the first and second ranges; in other words, the laser 2 of the assembly 1, has a detuning offset between ‘5’-‘7’ at units of k/2 at level of backscattering about 4·2γ/k.

Advantageously, the periodic changes in optical characteristics moving along said optical path defined by the resonator 5 ensures that the first and second ranges overlap a significant amount, allowing for the broad range of detuning offsets. In other words, the assembly 1 can operate to provide both, self-injection locking of the laser 2 using the backreflection provided by the resonator 5, and, the generation of multifrequency comb within the resonator so that a multi-frequency optical microresonator-based or resonator-based frequency comb (which has at least two frequencies that were generated in the resonator 5) is output from the assembly 1 (i.e. is provided at the output 3b of the wave guide 3), over a broad range of detuning offsets. Because the range of detuning offsets are broad, a user can more easily detune the assembly 1 so that both self-injection locking is achieved, and a multi-frequency optical microresonator-based or resonator-based frequency comb is output from the assembly 1.

In the most preferred embodiment of the assembly 1, the difference between the resonant frequency of the laser 2 and the resonant frequency of the resonator 5 is within a predefined range. For example, the difference between the resonant frequency of the laser 2 and the resonant frequency of the resonator 5 may be between k to 10k where k is a width of resonator's resonance; meaning that the resonant frequency of the laser 2 may be between k-10k smaller than the resonant frequency of the resonator 5.

In the most preferred embodiment of the assembly 1, the resonator 5 is configured to have a third order non-linearity. The resonator 5 may comprise any suitable material. Preferably the resonator 5 is composed of a material which has strong third order non-linearity. For example, the resonator 5 may comprise silicon, and/or silicon nitride and/or aluminium nitride. In a preferred embodiment the resonator 5 is of a photonic crystal resonator (PhCR) (which preferably include structural or nanopatterned material).

In the assembly of FIG. 1a the resonator 5 is configured to be ring-shaped, so the optical path 11 is circular. However, it should be understood that the resonator 5 may be configured to provide a close loop in any form; for example, the resonator 5 may be configured to be oval-shaped to provide an oval optical path, or the resonator 5 may be configured to be racetrack or other close loop providing optical path.

The resonator 5 may be configured in any suitable way to have a periodic change in optical characteristics moving along said optical path 11. For example, the resonator 5 may be configured to have a periodic change in an index of refraction, moving along said optical path 11; and/or the resonator 5 may be configured to have a periodic change in a material density heterogeneity, moving along said optical path 11. A periodic change in optical characteristics moving along said optical path 11, means that the optical characteristic of the resonator 5 change periodically moving along the optical path 11. The shape of the structural elements spaced by one period may take any suitable form; for example, the periodic change in optical characteristics moving along said optical path 11 may include sinusoidal peaks, or a triangle wave peaks, or a square wave peaks, or a sawtooth wave peaks and so on.

In one embodiment the periodicity ‘P’ of the periodic change in optical characteristics along said optical path 11 is equal to P=L/(2m), wherein ‘L’ is the length of the optical path and ‘m’ is an integer. For example, the periodicity of the changes in the optical characteristic in the resonator are preferably in the range from L/2 to L/200'000, where L is the length of the optical path 11. In another embodiment the periodicity of the changes in the optical characteristic in the resonator are preferably in the range from 0.1 λ/n to 1000 λ/n, where λ is the resonator resonance wavelength, n is the resonator's material refractive index. For example, the periodicity could be taken as 20 λ/n.

In the exemplary embodiment shown in FIG. 1a, the resonator 5 is configured to have a periodic change in an index of refraction, moving along said optical path 11. This periodic change in the index of refraction, moving along said optical path 11, is achieved by the resonator 5 comprising a plurality of structural element 5a placed close to the resonator's waveguide, each of which have equal dimensions.

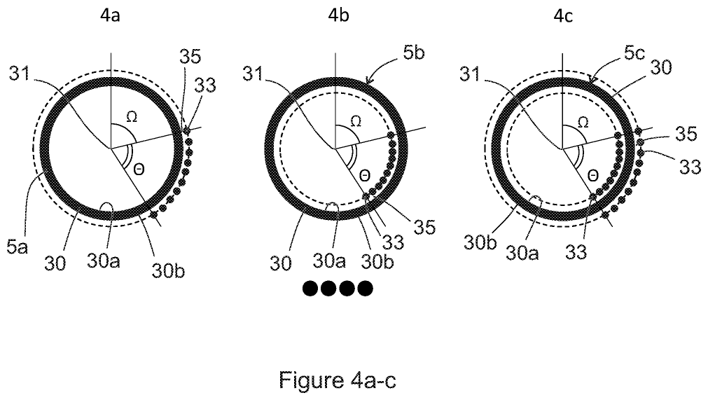

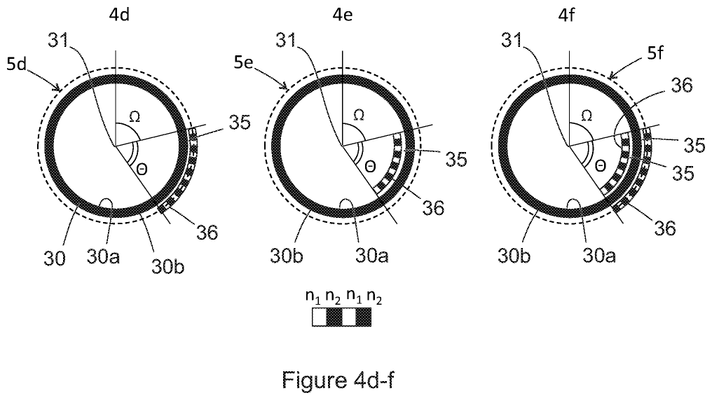

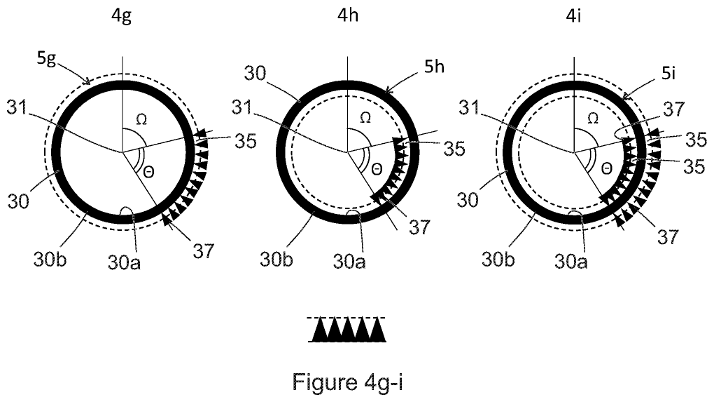

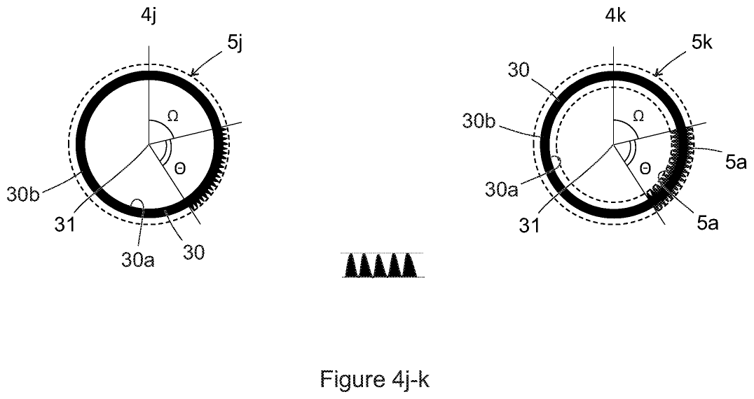

In another exemplary embodiments shown in FIG. 4, structural elements providing periodical change of optical characteristics moving along optical path can be performed in the upper cladding of the photonic chip with the resonator and placed close to the upper wall of the optical resonator's waveguide.

In an embodiment the periodic change in optical characteristics along said optical path 11 may depend on the desired resonance frequency of the backreflection; in an embodiment the period of the periodic changes in optical characteristics along said optical path 11 may be in the range 0.1 c/nν-1000 c/nν, where ν is the desired resonance frequency, n is the resonator's material refractive index and c is speed of light in vacuum. The size (amplitude of the periodical changes) or the quantity of the structural element 5a in the resonator 5 will dictate the amount or power of the back reflected light. Additionally choosing the angles Ω and θ for circular resonator amount of backscattering light and its phase (if necessary) can be adjusted. For example, the number of the said structural element can be chosen from the range 0,001·Ω·R·nν/c-10·Ω·R·nν/c, where Ω is the angle in the range (0, 2π), R is the radius of the resonator, ν is the desired resonance frequency of the backreflection, n is the resonator's material refractive index and c is speed of light in vacuum. Increasing the number of the structural elements 5a will increase the amount of the backreflection; and correspondingly decreasing the number of the structural element will decrease the amount of the backreflection.

In the assembly 1, the corrugations 5a of the resonator 5 are arranged to point towards a centre point 31 of the ring shape of the resonator 5 (the centre point 31 is a centre of an area which is encircled by the resonator 5). In another embodiment the corrugations 5a of the resonator 5 are arranged to point away from the centre point 31 of ring shape of the resonator 5. Each of said corrugations 5a have a triangular prim form, and an angle between two adjacent corrugations 5a is in the range 0-180 degrees.

Referring to the assembly 1, back-reflection is controlled by periodic nano-patterned corrugations of the resonator's inner wall. The constant angular corrugation period is θ=2π/(2m₀), where m₀ is the angular (azimuthal) mode number, for which a deliberate coupling between forward and backward propagating waves with a coupling rate γ is induced. Besides inducing the desired resonant back-reflection, the coupling leads to hybridized forward-and backward-propagating modes and a split resonance line shape (frequency splitting 2γ) in both transmission and reflection (as shown in FIG. 1b). Here, we only consider the lower frequency hybrid mode for pumping, as it corresponds to strong (spectrally local) anomalous dispersion, which prevents high-noise comb states. As the mode coupling impacts both dissipative kerr solitons (DKS) and self-injection locking (SIL) dynamics the choice of γ for SIL-based DKS is non-trivial.

As shown can be seen in the graph depicted in FIG. 1c strong back-reflection (i.e strong backscattering—in the present application the term “back-reflection” and “backscattering” have the same meaning) would lead to a wider SIL range and could hence enable robust access to DKS states. FIG. 1c shows the SIL range along with DKS existence range (valid for small γ) and the numerically computed DKS existence range for large γ, obtained through integration of the coupled mode equations which are known in the art.

The threshold power of the resonator 5 in the assembly 1 is different from that in a conventional ring resonator and its derivation critically requires consideration of the backward wave. For strong mode coupling (2γ/κ>1), the following approximation is derived:

$${{f}_{th}}^{2} = 4 \frac{γ}{κ} + \frac{κ}{γ} \qquad ( 1 )$$

Wherein ƒ=\sqrt{8ηω₀cn₂P/(κ²n²V_{eff})} is the normalized pump power or power of the laser 2 in the assembly 1 expressed in the dimensionless units, with the coupling coefficient η=½ (critical coupling meaning that no light is passing through the waveguide after the light beam is coupled into the optical ring resonator except the light that coupled out from the resonator through the same coupling element)., ω₀ is the resonance frequency of the resonator's mode which coincides with the light frequency of laser 2 in the assembly 1, c the speed of light in vacuum, P the input pump power in the power units, n the refractive index, n₂ nonlinear index meaning the dependency of refractive index from the laser intensity when intense laser beam passes through material (n=n₀+n₂·I, where I is intensity of laser light) and V_{eff} the mode volume meaning the volume occupied by light field in the resonator that is not equal to the volume of resonator's waveguide; γ is half of the mode splitting and κ is the resonance width.

The value of f²ₜₕ most preferably will not exceed the maximal power f² of laser 2 in the assembly 1. If the Modulation Instability (MI) threshold meaning the same here as parametric threshold pump power is reached at a detuning within the DKS existence range, then DKS can form spontaneously. In a resonator with a detuned frequency of laser 2, the existence range of DKS deviates strongly from that known from resonators without a detuned frequency of laser 2. In both conventional and detuned frequency resonators the DKS regime overlaps with the MI regime when initial optical microresonator-based or resonator-based frequency comb with at least two frequencies is formed and extends further towards larger detunings ζ₀.

Sometimes at larger frequency detunings multiple-DKS states can be formed when several short light pulses with different repetition rates circulate inside the resonator leading to generation of multifrequency comb with unpredictable and noisy envelop With regard to practical applications single-DKS states when only one short light pulse circulate inside the resonator, as opposed to states with multiple DKS, are highly desirable owing to their smooth squared hyperbolic secant spectral envelope and well-defined temporal output. In their formation process, DKS are seeded by MI, where the separation of the first pair of sidebands from the pump laser frequency in units of the resonator's free-spectral range (FSR) determines the number of generated DKS. A conservative criterion that guarantees single-DKS formation can be expressed as:

$$\frac{γ}{κ} > \frac{{f}^{2}}{8} \qquad ( 2 )$$

Wherein f is the normalized pump power or power of the laser 2 in the assembly 1 expressed in the dimensionless units, γ is the half of the mode splitting and κ is the resonance width

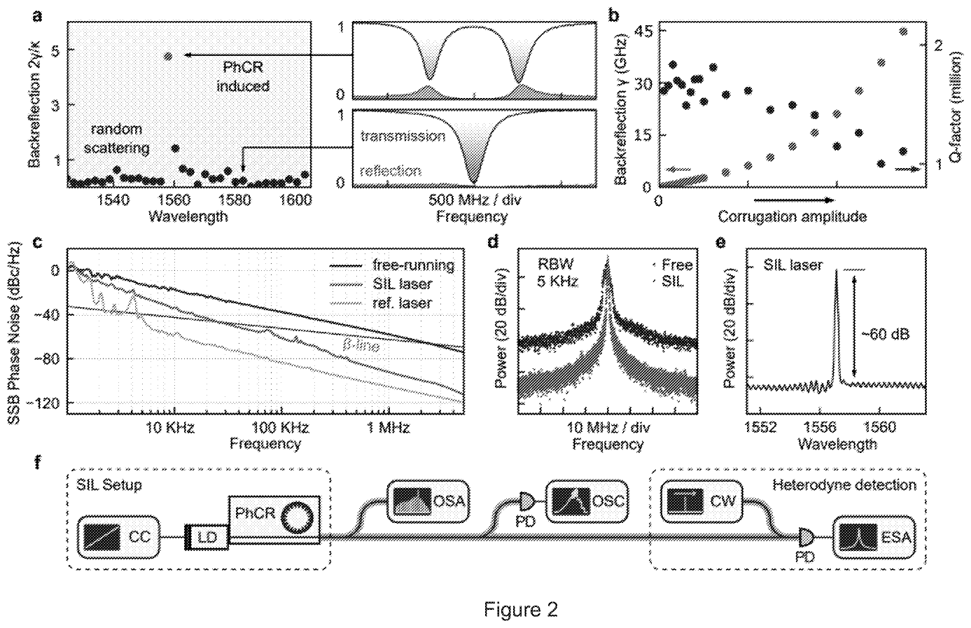

In an embodiment the resonator 5 of the assembly 1 of FIG. 1a is a critically coupled resonator that can be performed with varying corrugation amplitude and a free-spectral range (FSR) of 300 GHz (radius 75 μm). The resonator 5 may be characterize via frequency comb-calibrated laser scans, permitting to retrieve the resonators' dispersion D₂, the coupling rates γ, as well as the resonance widths κ over a broad spectral bandwidth. An example is shown in FIG. 2a, where indeed the back-scattering is random and γ/κ<<1 for most resonances. In marked contrast, a single pre-defined resonance to which the resonators corrugation is matched, exhibits significant back-reflection. FIG. 2b shows the dependence of γ and the Q-factor (Q=Ω₀/κ) on the corrugation amplitude. No noticeable degradation of the Q factor is observed up to γ≤5 GHz, and critically coupled linewidth are κ2π≈120 MHz; even for large coupling 180 γ≈45 GHz, the Q-factor is only halved. In the assembly 1 of FIG. 1a the laser 2 may comprise a semiconductor distributed feedback laser (DFB) or DFB laser diode having here the same meaning signifying semiconductor laser with spectrally selective resonator emitting one laser frequency with the usual linewidth 1-10 MHz; and the DFB may be butt-coupled to the waveguide 3 on a photonic chip, permitting an on-chip pump power of P=35 mW, corresponding to f²=9. For this value an ideal γ/κ∈(1.13, 2.13) can be obtained, based on Eqs. 1 and 2, ensuring MI-based spontaneous comb initiation and deterministic generation of single DKS. Based on these considerations we identify that the resonator 5 in the assembly 1, should preferably have a tailored coupling for the pump mode at 1557 nm of γ/κ≈2.1 (γ/2π≈250 MHz), towards the higher end of the ideal range, for a wide SIL range. Such a resonator 5 is critically coupled and exhibits anomalous group velocity dispersion (D₂=8 MHz). As shown for those values in FIG. 1c, the DKS existence and SIL ranges have significant overlap.

In the assembly 1 the laser 2 may comprises a DFB pump laser diode. The DFB pump laser diode is preferably mounted on a piezo translation stage to adjust the injection phase, an actuator which could also readily be achieved through on-chip heaters; to reduce the device footprint and allow for more resonators on the chip, this on-chip heater adjusting the injection phase has been omitted and not shown on FIG. 1. The transmitted light is collected by a lensed-fiber for further analysis as shown in FIG. 2f.

In the assembly 1, when the laser 2 of the assembly 1 is configured to have a coupled pump power of 25 mW (f²=6.4); the pump power is below the parametric threshold of multifrequency optical microresonator-based or resonator-based frequency comb generation. When the laser 2 is turned to provide an emission wavelength is closed to the lower-frequency pump resonance from the two spitted resonances shown in FIG. 1b (i.e. when a detuning offset is applied to the laser 2 to configure the laser to output an emission wavelength which is close to the lower-frequency pump resonance), a strong resonant backward-wave is generated, providing frequency-selective optical feedback resulting in SIL. It should be understood that preferably, a detuning offset is applied to the laser 2 by applying the appropriate electrical drive current to the laser 2; to increase the detuning offset the electrical drive current to the laser 2 should be increased; to decrease the detuning offset the electrical drive current to the laser 2 should be decreased. The electrical drive current is the current which is applied to the laser 2 which powers the laser to emit light; the more drive current that is applied to the laser the more lower frequency of laser light that will be emitted by the laser. The mentioned electrical drive current is a current which tunned and applied to the laser chip using external current controller. The SIL regime manifests itself as a rectangular-shaped dip in the transmission signal and, after optimizing the injection phase or phase of the laser light entering to the resonator and tuned by moving laser 2 further or closer to the input to the waveguide 3a using piezo actuator or by on-chip integrated heaters (not shown on the FIG. 1), extends over a wide range of electrical drive current values when laser frequency is equal to resonator's resonance frequency and doesn't change with changing the electrical drive current. In these conditions the significant narrowing from 1-10 MHz to 1-10 kHz of the laser line is happened and the laser became self-injection locked to the resonator's resonance (SIL-laser). The optical spectrum of the laser 2 in the SIL regime is shown in FIG. 2e, showing a single-mode suppression ratio (SMSR) ˜60 dB. The beatnote of the SIL laser with a table-top low-noise continuous wave (CW) laser is shown in FIG. 2d. In addition, the SIL-laser phase noise is shown in FIG. 2c, which shows a drastically lower than that of the free-running DFB outside the SIL regime.

In the assembly 1, when the laser 2 of the assembly 1 is configured to have a coupled pump power of 35 mW (f²=9); the couple pump power of 35 mW (f²=9) is above the parametric threshold of multifrequency optical microresonator-based or resonator-based frequency comb generation.

To observe the DKS-based optical microresonator-based or resonator-based frequency comb generation of the assembly 1 a set-up shown in FIG. 2f can be used wherein the assembly 1 is operably connected to This can be see using a set up shown in FIG. 2f; wherein the laser 2 (which is in the form of a Laser Diode (LD)) is optically coupled to a current controller (CC) (the CC can be used to adjust the electrical drive current to the laser 2 so as to adjust the detuning offset which is applied to the laser 2); the output of the optical wave guide 3 is connected to: an optical spectrum analyser (OSA) and an electrical spectrum analyser (ESA), and an oscilloscope (OSC), and a photodiode (PD); and a continuous-wave laser (CW) is also optically coupled to the PD.

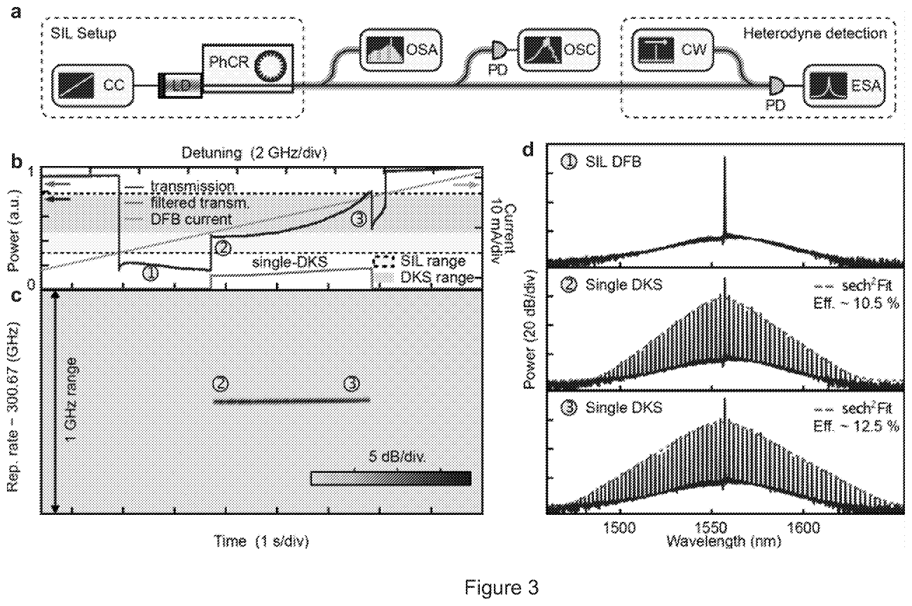

When the DFB's electrical drive current is slowly (within ca. 10 s) tuned to scan the emission wavelength across the lower frequency pump resonance, in both forward and backward direction (e.g. increasing and decreasing wavelength, resp.) and the optical spectrum in transmission is monitored (the optical spectrum of the transmitted light and the optical spectrum of the generated frequency comb are both monitored at the output of the waveguide 3), it can be observed that the exact tuning rate in the SIL regime when increasing (decreasing) the DFB pump current follows a non-trivial behaviour that may include non-monotonic sections; the scan outside the SIL range is however monotonic in frequency. Upon entering the SIL regime (again marked by pronounced dip of the transmitted power), at first the optical spectrum at the output of the wave guide 3, has only the single optical frequency of the SIL pump laser, as shown in FIG. 3a-1 <need better numbering of graphs>. Continuing the scan of the emission wavelength, an abrupt transition into a single-DKS optical microresonator-based or resonator-based frequency comb state occurs, as shown in FIG. 3a-2; such single-DKS states are characterized by a smooth squared hyperbolic-secant amplitude and a pulse repetition rate that corresponds to the resonator's FSR; these characteristics are highly-desirable for some applications. Further continuing the scan induces a surprizing second abrupt transition into another single-DKS state as shown in FIG. 3a-3. Scanning further causes the DKS to disappear, with the system returning to continues wave self-injection locking (CW SIL) (spectrum similar to FIG. 3a-1), before eventually exiting the SIL regime entirely. When repeated, each scan shows the same SIL dynamics (i.e. series of optical spectra, or, series of soliton states changing each other when detuning is changed) including deterministic single-DKS generation. Reversing the scan direction qualitatively yields the same SIL dynamics but in reversed order.

The 300 GHz DKS repetition rate beatnote of the assembly 1 can be recorded using the setup shown in FIG. 3b. As this signal would not be directly detectable, modulation sidebands around a pair of adjacent DKS comb lines are generated electro-optically. Their beating creates a signal at lower frequency, from which the repetition rate signal can be reconstructed. When the laser 2 in the assembly 1 is a DFB laser 2, FIG. 3c shows the reconstructed repetition rate signal obtained during a scan of the laser 2 in both forward and backward scanning directions. The two distinct spectral regimes are also manifest in this signal: in regime 2 a single low-noise repetition rate beatnote is present, whereas in regime 3 additional sidebands (ca. ±200 MHz) indicate a breathing soliton, similar to so far unexplained breathing phenomena in conventionally driven photonic crystal resonators (PhCRs) at large detuning. In the backward scan, the reversed dynamics is observed (the additional breathing towards the end of the backward scan is well-known from conventionally driven DKS). The transmitted power as well as the power of a bandpass-filtered spectral portion in the long-wavelength wing of the generated optical microresonator-based or resonator-based frequency combs (as an indicator for comb formation) along with the lasers drive current, during when the laser 2 is scanned, are shown in FIG. 3d. Here, the SIL regime is evidenced by sharp drops of the (full) transmission from the base level in both forward and backward scan directions. The DKS regime is marked by the non-zero bandpass filtered power within the SIL regime.

FIG. 3d also shows that the breathing oscillation is only visible in the recorded power for the lowest breathing frequencies in the backward-scan, due to the limited 100 MHz bandwidth of the utilized photo-detectors. For comparison, FIG. 3e shows a similar transmission and filtered power trace obtained with a non-PhCR microresonator of the same FSR.

As mentioned, the resonator 5 of the assembly 1 may be configured in any suitable way to have a periodic change in optical characteristics moving along said optical path 11. FIGS. 4a-4k illustrate resonators 5a-l which are configured in different ways to have a periodic change in optical characteristics moving along said optical path 11.

FIG. 4a shows a resonator 5a which comprises a first ring portion 30 having an inner surface 30a which is a surface which is facing the centre point 31 of the area encircled by the first ring portion 30 of the resonator 5a, and an outer surface 30b which is a surface which is facing away from the centre point 31. The resonator 5a further comprises a series of round or spherical structural components 33 arranged opposite to the outer surface 30b of the first ring portion 30 (i.e. the series of spherical members 33 are arranged in a ring around the outer surface 30b). The structural components 33 are equally spaced apart (i.e. the distance between the two adjacent structural components 33 is the same as the distance between any other two adjacent structural components 33). Each structural components 33 is spaced an equal distance from the outer surface 30b of the first ring 30. Each structural components 33 is optically coupled to the first ring portion 30, and also optically coupled to each other structural components 33, preferably by means of an evanescent field 35. Preferably each structural component 33 and the first ring portion 30 are composed of the same light conducting material; for example, each spherical member 33 and the first ring portion 30 may be composed of silicon nitride or silicon oxide material.

FIG. 4b shows a resonator 5b which has many of the same features as the resonator 5a shown in FIG. 4a and like features are awarded the same reference numbers. Unlike the resonator 5a shown in FIG. 4a, in the resonator 5b shown in FIG. 4b the series of structural elements 33 are arranged opposite the inner surface 30b of the first ring portion 30.

FIG. 4c shows a resonator 5c which has many of the same features as the resonator 5c shown in FIG. 4a and like features are awarded the same reference numbers. Unlike the resonator 5a shown in FIG. 4a, the resonator 5c shown in FIG. 4c comprises both a series of structural components 33 arranged opposite to the outer surface 30b of the first ring portion 30 (i.e. the structural components 33 are arranged in a ring around the outer surface 30b), and also a series of spherical members 33 which are arranged opposite the inner surface 30b of the first ring portion 30. In other words, the resonator 5c comprises a first ring portion 30, and a first ring of structural components 33 arranged opposite to the outer surface 30b of the first ring portion 30, and a second ring of structural components 33 arranged opposite to the inner surface 30a of the first ring portion 30.

FIG. 4d shows a resonator 5d which comprises a first ring portion 30 having an inner surface 30a which is a surface which is facing the centre point 31 of the first ring portion 30 (i.e. the centre point 31 is a centre of an area which is encircled by the resonator 5d), and an outer surface 30b which is a surface which is facing away from the centre point 31. The resonator 5d further comprises a series of cube (or rectangular) structural elements 36 having alternating index of refraction n₁ and n₂ (in other words a first cube (or rectangular) structural element has an index of refraction n₁ and the cube (or rectangular) structural elements which are adjacent to the first cube (or rectangular) structural element have a index of refraction n₂). The cube (or rectangular) structural elements 36 are arranged opposite to the outer surface 30b of the first ring portion 30 (i.e. the cube (or rectangular) structural element 36 are arranged in a ring around the outer surface 30b). The cube (or rectangular) structural elements 36 are equally spaced apart (i.e. the distance between the two adjacent cube (or rectangular) structural elements 36 is the same as the distance between any other two adjacent cube (or rectangular) structural elements 36). Each cube members 36 is spaced an equal distance from the outer surface 30b of the first ring 30. Each cube (or rectangular) structural element 36 is optically coupled to the first ring portion 30, and also optically coupled to each of the other cube (or rectangular) structural elements 36, preferably by means of an evanescent field 35. Preferably one type of the cube (or rectangular) structural elements 36 and the first ring portion 30 are composed of the same light conducting material having refractive index n₁ and another type of the cube members is composed of another light conducting material or the same material having dopants.

FIG. 4e shows a resonator 5e which has many of the same features as the resonator 5d shown in FIG. 4d and like features are awarded the same reference numbers. Unlike the resonator 5d shown in FIG. 4d, in the resonator 5e the series of cube (or rectangular) structural elements 36 are arranged opposite the inner surface 30b of the first ring portion 30.

FIG. 4f shows a resonator 5f which has many of the same features as the resonator 5d shown in FIG. 4d and like features are awarded the same reference numbers. Unlike the resonator 5d shown in FIG. 4d, the resonator 5f comprises both a series of cube (or rectangular) structural elements 36 arranged opposite to the outer surface 30b of the first ring portion 30 (i.e. the cube (or rectangular) structural elements 36 are arranged in a ring around the outer surface 30b) and also a series of cube (or rectangular) structural elements 36 which are arranged opposite the inner surface 30b of the first ring portion 30. In other words, the resonator 5f comprises a first ring portion 30, and a first ring of cube (or rectangular) structural elements 36 is arranged opposite to the outer surface 30b of the first ring portion 30, and a second ring of cube (or rectangular) structural elements 36 is arranged opposite to the inner surface 30a of the first ring portion 30.

FIG. 4g shows a resonator 5g which comprises a first ring portion 30 having an inner surface 30a which is a surface which is facing the centre point 31 of the first ring portion 30 (the centre point 31 is a centre of an area which is encircled by the resonator 5g), and an outer surface 30b which is a surface which is facing away from the centre point 31 which the first ring portion 30 encircles. The resonator 5g further comprises a series of triangular prims 37 arranged opposite to the outer surface 30b of the first ring portion 30 (i.e. the triangular prims 37 are arranged in a ring around the outer surface 30b). The triangular prims 37 are equally spaced apart (i.e. the distance between the two adjacent triangular prims 37 is the same as the distance between any other two adjacent triangular prims 37). Each triangular prim 37 is spaced an equal distance from the outer surface 30b of the first ring 30. Each of the triangular prims 37 is arranged so that it is pointing towards the centre point 31. Each triangular prims 37 is optically coupled to the first ring portion 30, and also optically coupled to each other triangular prims 37, preferably by means of an evanescent field 35. Preferably each triangular prim 37 and the first ring portion 30 are composed of the same light conducting material; for example each triangular prim 37 and the first ring portion 30 may be composed of photonic crystal.

FIG. 4h shows a resonator 5h which has many of the same features as the resonator 5g shown in FIG. 4g and like features are awarded the same reference numbers. Unlike the resonator 5g shown in FIG. 4g, in the resonator 5h the series of triangular prims 37 are arranged opposite the inner surface 30b of the first ring portion 30. Each of the triangular prims 37 is arranged so that it is pointing away from the centre point 31.

FIG. 4i shows a resonator 5i which has many of the same features as the resonator 5g shown in FIG. 4g and like features are awarded the same reference numbers. Unlike the resonator 5g shown in FIG. 4g, the resonator 5i comprises both a series of triangular prims 37 arranged opposite to the outer surface 30b of the first ring portion 30 (i.e. the triangular prims 37 are arranged in a ring around the outer surface 30b) and also a series of triangular prims 37 which are arranged opposite the inner surface 30b of the first ring portion 30. In other words, the resonator 5i comprises a first ring portion 30, and a first ring of triangular prims 37 arranged opposite to the outer surface 30b of the first ring portion 30, and a second ring of triangular prims 37 arranged opposite to the inner surface 30a of the first ring portion 30. Each triangular prims 37 in the first ring is arranged so that it is pointing towards the centre point 31, and each triangular prims 37 in the second ring is arranged so that it is pointing away from the centre point 31.

FIG. 4j shows a resonator 5j which has many of the same features as the resonator 5 shown in FIG. 1a. The resonator 5j comprises a series of corrugations 5a which are each arranged to point away from the centre point 31 that the resonator 5j encircles. The resonator 5j comprises a first ring portion 30 having an inner surface 30a which is a surface which is facing the centre point 31 of the first ring portion 30 (the centre point 31 is a centre of an area which is encircled by the resonator 5j); an outer surface 30b, which is facing away from the centre point 31 which the first ring portion 30 encircles, is defined by a surface of the corrugations 5a. In this example the corrugations 5a are integral to the first ring portion 30. The corrugations 5a may have the same features as the corrugation of the resonator 5 of the assembly 1 shown in FIG. 1a. Preferably the corrugations 5a and the first ring portion 30 are composed of the same light conducting material; for the corrugations 5a and the first ring portion 30 may be composed of photonic crystal.

FIG. 4k shows a resonator 5k which has many of the same features as the resonator 5 shown in FIG. 1a and the resonator 5j shown in FIG. 4j and like features are awarded the same reference numbers. The resonator 5k comprises a series of corrugations 5a which are arranged to point towards a centre point 31 that the resonator 5k encircles, and also comprises a series of corrugations 5a which are arranged to point away from the centre point 31 that the resonator 5k encircles.

In the resonator 5 of FIG. 1 and also in the resonator 5j of FIG. 4j and also in the resonator 5k of FIG. 4k, the corrugations (and preferably a first ring portion), are integral to the resonator 5,5j,5k.

According to a further aspect of the present invention there is provided a method of providing a optical microresonator-based or resonator-based frequency comb at an output of a waveguide, the method comprising the steps of, providing an assembly according to any one of the above-described assembly embodiments (in this example the method will use the assembly 1 shown in FIG. 1a); generating in the resonator 5 a backreflection which has a predefined frequency, and using that backreflection for self-injection locking of the laser 2; and generating a plurality of frequencies in the resonator 5, so that a multi-frequency optical resonator-based frequency comb which comprises the plurality of frequencies that were generated in the resonator 5, is output from the assembly 1.

A multi frequency comb can be generated in a resonator using any suitable mean; for example a multi frequency comb can be generated in a resonator by solitions, such as dissipative kerr solitions for example, which are generated in the resonator. In another example a multi frequency comb can be generated in a resonator by platicons which are generated in the resonator. Accordingly, the step of generating a plurality of frequencies in the resonator comprises generating any one or more of, solitons and/or dissipative kerr solitions and/or platicons within the resonator.

The amount of backreflection which is generated, will provide a first detuning range in which self-injection locking of the laser using said backreflection is achieved, and, a second detuning range wherein an optical resonator-based frequency comb can be generated within the resonator 5, and wherein the first and second detuning ranges at least partially overlap, so that a multi-frequency microcomb is output from the wave guide 3, when the assembly 1 is in operation. In a preferred embodiment the amount of backreflection which is generated, will provide a first detuning range in which self-injection locking of the laser using said backreflection is achieved, and, a second detuning range wherein kerr solitions and/or platicons can be generated within the resonator, and wherein the first and second ranges at least partially overlap, so that a multi-frequency microcomb is output from the wave guide, when the assembly is in operation.

The method preferably comprises, providing detuning which is within said overlap of the first and second ranges, by applying a frequency offset to the laser and/or by applying a frequency offset to the resonant frequency of the resonator, so that both self-injection locking of the laser occurs and a multi-frequency optical resonator-based frequency comb is output from the wave guide. In an embodiment resonator has a plurality of resonant frequencies; and the method comprises the step of selecting one of said resonant frequencies; and adjusting the resonator can provide a backreflection which is at a selected one of said plurality of resonant frequencies of the resonator.

In a preferred embodiment the method comprises the steps of, obtaining a graph depicting the relationship, between detuning provided by applying a frequency offset to the laser and/or detuning provided by applying a frequency offset to the resonant frequency of the resonator, an amount of backreflection generated in the resonator, an multifrequency optical resonator-based frequency comb range, and a self-injection locking range, of the assembly; identifying a region on the graph where the multifrequency optical resonator-based frequency comb existence range and self-injection locking range overlap; identifying a range, or level, for detuning offset to be provided by identifying on the graph a range, or level, of detuning offset which corresponds with said identified region. A preferred embodiment of the method comprises the steps of obtaining a graph depicting the relationship, between detuning provided by applying a frequency offset to the laser and/or detuning provided by applying a frequency offset to the resonant frequency of the resonator, an amount of backreflection generated in the resonator, a dissipative kerr solitions range, and a self-injection locking range, of the assembly; identifying a region on the graph where the dissipative kerr solitions range and self-injection locking range overlap; and identifying a range, or level, for detuning offset to be provided by identifying on the graph a range, or level, of detuning offset which corresponds with said identified region.

Identifying, on the graph, a first detuning offset range which is a range of detuning offset values which, when any one of the detuning offsets in the first range is applied to the laser 2, self-injection locking of the laser in the assembly 1, using the backreflection, will occur when the assembly 1 is in operation; and identifying, on the graph, a second detuning offset range wherein the second detuning offset range is a range of detuning offset values which, when any one of the detuning offsets in the second range is applied to the laser, dissipative kerr solitions are generated in the resonator resulting in the generation of at least two frequencies in the resonator. Identifying the overlap of the first range and second range. The method preferably comprise applying a detuning offset to the laser 2 which has a value which is within said overlap the first and second ranges, so that both self-injection locking of the laser 2 occurs and the multi-frequency optical microresonator-based or resonator-based frequency comb is output from the assembly 1.

If the first and second ranges do not overlap, then the method may comprise a step of replacing the resonator 5 with another resonator 5 which has a different periodic change in optical characteristics moving along said optical path 11, and then repeating all the afore-mentioned steps. Additionally, or alternatively, if the first and second ranges do not overlap, then the method may comprise a step of, adjusting the laser 2 so that it emits a light which has a different predefined frequency range, and then repeating all the afore-mentioned steps; or replacing the laser 2 with another laser which can emit a light which has a different predefined frequency range, and then repeating all the afore-mentioned steps.

In an embodiment the method comprises the step of adjusting the position of the laser so as to tune the phases of light which are emitted from the laser into the waveguide and received by the resonator, comprises, using a resistance microheater on the waveguide 3 placed between laser and resonator which is operable to thermally change the refractive index of the waveguide. A voltage is applied to the resistance microheater to cause the resistance microheater to thermally change the refractive index of the waveguide; the more voltage that is applied to the resistance microheater the more the microheater the bigger change in the refractive index of the waveguide.

In an embodiment the method may comprise a step of, applying a detuning offset to the laser so that frequency of light which is emitted by the laser into the waveguide and received by the resonator, and the frequency of the backreflection, are tuned to maximize the size of the first detuning range.

Various modifications and variations to the described embodiments of the invention will be apparent to those skilled in the art without departing from the scope of the invention as defined in the appended claims. Although the invention has been described in connection with specific preferred embodiments, it should be understood that the invention as claimed should not be unduly limited to such specific embodiment.

1. An optical assembly (1) comprising,
a laser (2) which is operable to emit light;
an optical wave guide (3) having an input (3ₐ) and an output (3_{b}), the input (3ₐ) of the optical wave guide (3) being optically coupled to the laser (2) so that the laser (2) can input light to the wave guide (3);
a resonator (5) which is optically coupled to the wave guide (3) between the input (3ₐ) of the wave guide (3) and the output (3_{b}) of the wave guide (3); and
wherein the resonator (5) has a resonant frequency, and wherein the resonator (5) defines an optical path (11); and
wherein the resonator (5) is configured so that said optical path (11) is a closed loop; and
wherein the resonator (5) is configured to have a periodic change in optical characteristics along said optical path (11) so that the resonator (5) can provide a backreflection which is at the resonant frequency of the resonator; and
wherein the periodic change in optical characteristics along said optical path (11) provide an amount of said backreflection, which will provide a first detuning range in which self-injection locking of the laser using said backreflection is achieved, and, a second detuning range wherein a multifrequency comb can be generated within the resonator (5); and
wherein the first and second ranges at least partially overlap, so that both self-injection locking of the laser will occur and an optical resonator-based multifrequency comb is output from the wave guide (3), when the assembly (1) is in operation.

2. An assembly according to claim 1 wherein the amount of said backreflection y is satisfies the formula γ>ƒ²κ/8, wherein ƒ=\sqrt{8ηω₀cn₂P/(κ²n²V_{eff})} is a normalized pump power of the laser 2, η is a coupling coefficient, ω₀ is the resonance frequency of the resonator, c is the speed of light in a vacuum, P is an input pump power, n a refractive index, n₂ is a nonlinear index, and V_{eff} is a mode volume.

3. An assembly according to claim 1 or 2 wherein the first and second ranges overlap by at least an amount equal to a line width of the laser when self-injection locked.

4. An assembly according to any one of the preceding claims wherein the resonator has a plurality of resonant frequencies; and wherein the resonator is configured to have a periodic change in optical characteristics along said optical path so that the resonator can provide a backreflection which is at a selected one or more of said plurality of resonant frequencies of the resonator.

5. An assembly according to claim any one of the preceding claims, wherein the resonator-based multi-frequency comb which is output from the wave guide comprises at least two frequencies that were generated in the resonator.

6. An assembly according to any one of the preceding claims, wherein a difference between a frequency of light emitted by the laser into the wave guide, and the resonance frequency of the resonator, is equal to a value which is within said overlap of the first and second ranges.

7. An assembly according to any one of the preceding claims wherein the spatial periodicity ‘P’ of the periodic change in optical characteristics along said optical path is equal to λ/(2·n) wherein λ is the resonant wavelength of the resonator, n is the refractive index of the resonator's material.

8. An assembly according to claim 4 wherein the laser is operable to emit light into the waveguide which comprises at a predefined frequency wherein the difference between said predefined frequency of the light emitted by the laser into the waveguide and said selected one of said plurality of resonant frequencies of the resonator, is within a predefined range.

9. An assembly according to claim 8 wherein the predefined range is from κ to 10κ, wherein κ is a resonance width of the resonator.

10. An assembly according to any one of the preceding claims wherein the resonator has a third order non-linearity.

11. An assembly according to any one of the preceding claims wherein, the laser comprises a semiconductor laser, and wherein the semiconductor laser is detuned by applying a predefined injection current to the semiconductor laser.

12. An assembly according to any one of the preceding claims, further comprising a microheater, wherein the microheater is operably connected to the resonator so that the microheater is operable to heat the resonator to thermally change a refractive index of the resonator and hence its resonance frequency value.

13. An assembly according to any one of the preceding claims wherein the resonator comprises piezo electric material and wherein the assembly further comprises a piezo stack actuator which is operably connected to the resonator, wherein the piezo stack actuator is operable to apply a stain to the resonator to change a refractive index of the resonator so as to change the resonant frequency of the resonator.

14. An assembly according to any one of the preceding claims wherein the resonator is configured to have a periodic change in an index of refraction, along said optical path.

15. An assembly according to any one of the preceding claims wherein the resonator is configured to have a periodic change in a material density heterogeneity, along said optical path.

16. An assembly according to any one of the preceding claims, wherein the resonator comprises a plurality of corrugations, each of which have equal dimensions, which provide said periodic change in optical characteristics along said optical path.

17. An assembly according to claim 14, wherein the number of corrugations is 20-200000.

18. A assembly according to claim 16 or 17 wherein the amplitude of each corrugation is between 5 nm and 2 micrometers.

19. An assembly according to any one of claim 16-18, wherein the resonator is a ring shaped and the corrugations are arranged to point towards a centre of the ring shape; or wherein the corrugations are arranged to point away from a centre of the ring shaped.

20. An assembly according to any one of claim 16-19, wherein each of said corrugations have a triangular prism form, and an angle between two adjacent corrugations is between 0-180 degrees.

21. An assembly according to any one of the preceding claims, wherein the assembly comprises a photonic chip which comprise said resonator; and wherein photonic chip comprises a cladding, and wherein said optical path is located in the cladding.

22. An assembly according to any one of the preceding claims, wherein the resonator-based multi-frequency comb which is output from the wave guide comprises at least two frequencies that were generated in the resonator.

23. An assembly according to any one of the preceding claims, wherein the resonator comprises a photonic crystal ring resonator.

24. An assembly according to any one of the preceding claims wherein the resonator is optically coupled to the wave guide by means of an evanescent field.

25. An assembly according to any one of the preceding claims wherein the input of the optical wave guide is optically coupled to the laser, so that the laser light frequency components which coincide in frequency with the resonator resonance frequencies can propagate along the waveguide to the resonator.

26. An assembly according to any one of the preceding claims wherein the laser comprises a Fabry-Perot laser diode having a plurality of frequencies.

27. A method of providing a multi-frequency optical resonator-based frequency comb, comprising the steps of,
providing an assembly according to any one of the preceding claims;
generating in the resonator (5) a backreflection which has a predefined frequency, and using that backreflection for self-injection locking of the laser (2); and
generating a plurality of frequencies in the resonator 5, so that a multi-frequency optical resonator-based frequency comb which comprises the plurality of frequencies that were generated in the resonator 5, is output from the assembly 1.

28. A method according to claim 27 wherein the step of generating a plurality of frequencies in the resonator comprises generating optical resonator-based frequency comb in the resonator 5.

29. A method according to claim 27 or 28 wherein the step of generating a plurality of frequencies in the resonator comprises generating any one or more of, solitons and/or dissipative kerr solitions and/or platicons within the resonator.

30. A method according to any one of claims 27-29 wherein the amount of backreflection which is generated will provide a first detuning range, wherein the first detuning range is a range of detuning values in which there is self-injection locking of the laser using said backreflection, and, wherein the assembly has a second detuning range wherein the second detuning range wherein an optical resonator-based frequency comb can be generated within the resonator (5), and wherein the first and second detuning ranges at least partially overlap, so that a multi-frequency microcomb is output from the wave guide (3), when the assembly (1) is in operation.

31. A method according to claim 30 wherein said second detuning range is a range of detuning values wherein kerr solitions and/or platicons can be generated within the resonator.

32. The method according to any one of claims 30-31 comprising the steps of, providing detuning which is within said overlap of the first and second ranges, by applying a frequency offset to the laser and/or by applying a frequency offset to the resonant frequency of the resonator, so that both self-injection locking of the laser occurs and a multi-frequency optical resonator-based frequency comb is output from the wave guide.

33. A method according to any one of claims 27-32 comprising the steps of, obtaining a graph depicting the relationship, between detuning provided by applying a frequency offset to the laser and/or detuning provided by applying a frequency offset to the resonant frequency of the resonator, an amount of backreflection generated in the resonator, and multifrequency optical resonator-based frequency comb range, and a self-injection locking range, of the assembly;
identifying a region on the graph where the multifrequency optical resonator-based frequency comb existence range and self-injection locking range overlap;
identifying a range, or level, for detuning offset to be provided by identifying on the graph a range, or level, of detuning offset which corresponds with said identified region.

34. A method according to claim 33 wherein the multifrequency optical resonator-based frequency comb existence range comprises any one of a dissipative kerr solitions range, a solitions range, and/or a platicons range.

35. A method according to any one of claims 27-34 comprising the steps of, obtaining a graph depicting the relationship, between detuning provided by applying a frequency offset to the laser and/or detuning provided by applying a frequency offset to the resonant frequency of the resonator, an amount of backreflection generated in the resonator, a dissipative kerr solitions range, and a self-injection locking range, of the assembly;
identifying a region on the graph where the dissipative kerr solitions range and self-injection locking range overlap;
identifying a range, or level, for detuning offset to be provided by identifying on the graph a range, or level, of detuning offset which corresponds with said identified region.

36. A method according to any one of claims 30-35, comprising the step of adjusting the position of the laser so as to tune the phases of light which are emitted from the laser into the waveguide and received by the resonator, and which are backreflected from the resonator, so as to maximize the width of the first detuning range.

37. A method according claim 30-35, comprising the step of tuning the phases of light which are emitted from the laser into the waveguide and received by the resonator, so as to maximize the width of the first detuning range using a resistance microheater on the waveguide 3 placed between laser 2 and resonator 5 which is operable to thermally change the refractive index of the waveguide.

38. A method according to any one of claims 30-37 further comprising the step of, applying a detuning offset to the laser to increase the amount of backscattering to maximize the size of the first detuning range, while also maintaining at least a partial overlap between the first and second detuning ranges.

39. A method according to claim 38 comprising the step of, applying a detuning offset to the laser so that frequency of light which is emitted by the laser into the waveguide and received by the resonator, and the frequency of the backreflection, are tuned to increase the amount of backscattering to maximize the size of the first detuning range.

40. The method according to claim 27-39, wherein the resonator has a plurality of resonant frequencies; and the method comprises the step of selecting one or more of said resonant frequencies of the resonator; and adjusting the resonator to provide backreflection(s) which is/are at the one more selected resonant frequencies of the resonator.
